(19) United States
(12) Patent Application Publication
(10) Pub. No.: US 2026/0310056 A1
(43) Pub. Date: Oct. 8, 2026

(54) PROJECTOR

(71) Applicant: SEIKO EPSON CORPORATION, Tokyo (JP)

(72) Inventors: Yosuke NAKATA, MATSUMOTO-SHI (JP); Keita TSUKIOKA, MATSUMOTO-SHI (JP)

(21) Appl. No.: 19/640,811

(22) Filed: Apr. 7, 2026

(30) Foreign Application Priority Data
Apr. 8, 2025 (JP) 2025-063482

(51) Int. Cl. G03B 21/16; G03B 21/20; H05K 7/20

(52) U.S. Cl. CPC G03B 21/16; G03B 21/2013; H05K 7/20145; H05K 7/20154; H05K 7/20209

(57) ABSTRACT

A projector includes a light source device, an image forming device, a projection optical device, and a cooling device. The light source device includes a first light source that emits first light, a second light source that emits second light, a third light source that emits third light. The image forming device includes a light modulation section that modulates light incident from the light source device, the cooling device includes a first fan that supplies cooling air, a heating amount of the first light source is smaller than a heating amount of the second light source and a heating amount of the third light source, the third light source has a largest heating amount and the second light source has a lowest management temperature, and the cooling device adjusts an air-flow amount of the cooling air by the first fan.

The present application is based on, and claims priority from JP Application Serial Number 2025-063482, filed Apr. 8, 2025, the disclosure of which is hereby incorporated by reference herein in its entirety.

### BACKGROUND

### 1. Technical Field

The present disclosure relates to a projector.

### 2. Related Art

For example, a projector disclosed in JP-A-2013-88743 includes a cooling fan for cooling optical components such as a liquid crystal light valve and a polarization conversion element that are arranged in a housing and serve as heat sources. In such a projector, a case of cooling heat sources having different heating amounts and different management temperatures is also conceivable. As the heat source, for example, a liquid crystal light valve, a light source, or the like is conceivable.

In a case where there are a plurality of heat sources having different temperature characteristics, if temperatures of the plurality of heat sources are controlled using one cooling fan, there is a problem that the control becomes complicated. When a cooling fan is provided for each heat source, a plurality of cooling fans need to be installed, which causes a problem of an increase in the size of a device configuration.

### SUMMARY

In order to solve the above-described problem, according to a first aspect of the present disclosure, a projector including a light source device; an image forming device that forms image light from light emitted from the light source device; a projection optical device that projects the image light emitted from the image forming device; and a cooling device that cools the light source device and the image forming device, wherein the light source device includes a first light source that emits first light in a first wavelength band, a second light source that emits second light in a second wavelength band different from the first wavelength band, and a third light source that emits third light in a third wavelength band different from the first wavelength band and the second wavelength band, the image forming device includes a light modulation section that modulates light incident from the light source device based on image information, the cooling device includes a first fan that supplies cooling air to the first light source and the light modulation section, a heating amount of the first light source is smaller than a heating amount of the second light source and a heating amount of the third light source, among the first light source, the second light source, and the third light source, the third light source has a largest heating amount and the second light source has a lowest management temperature, and the cooling device adjusts an air-flow amount of the cooling air by the first fan based on temperature information of the image forming device and temperature information of the first light source is provided.

According to a second aspect of the present disclosure, a projector including a light source device; an image forming device that forms image light from light emitted from the light source device; a circuit substrate that controls the light source device and the image forming device; a projection optical device that projects the image light emitted from the image forming device; and a cooling device that cools the circuit substrate and the image forming device, wherein the circuit substrate includes a first circuit component, a second circuit component, and a third circuit component, the image forming device includes a light modulation section that modulates light incident from the light source device based on image information, the cooling device includes a first fan that supplies cooling air to the first circuit component and the light modulation section, a heating amount of the first circuit component is less than a heating amount of the second circuit component and a heating amount of the third circuit component, among the first circuit component, the second circuit component, and the third circuit component, the third circuit component has a highest heating amount and the second circuit component has a lowest management temperature, and the cooling device adjusts an air-flow amount of the cooling air by the first fan based on temperature information of the image forming device and temperature information of the first circuit component is provided.

### BRIEF DESCRIPTION OF THE DRAWINGS

FIG. 1 is a schematic configuration diagram of a projector.

FIG. 2 is a diagram illustrating a cooling configuration of the projector.

FIG. 3 is a cross-sectional view taken along line III-III in FIG. 2.

### DESCRIPTION OF EMBODIMENTS

Hereinafter, an embodiment of the present disclosure will be described in detail with reference to the drawings. In the drawings used in the following description, for the sake of easy understanding of features, there are cases where characteristic portions are enlarged for convenience, and the dimensional ratios and the like of the respective components are not necessarily the same as the actual ones.

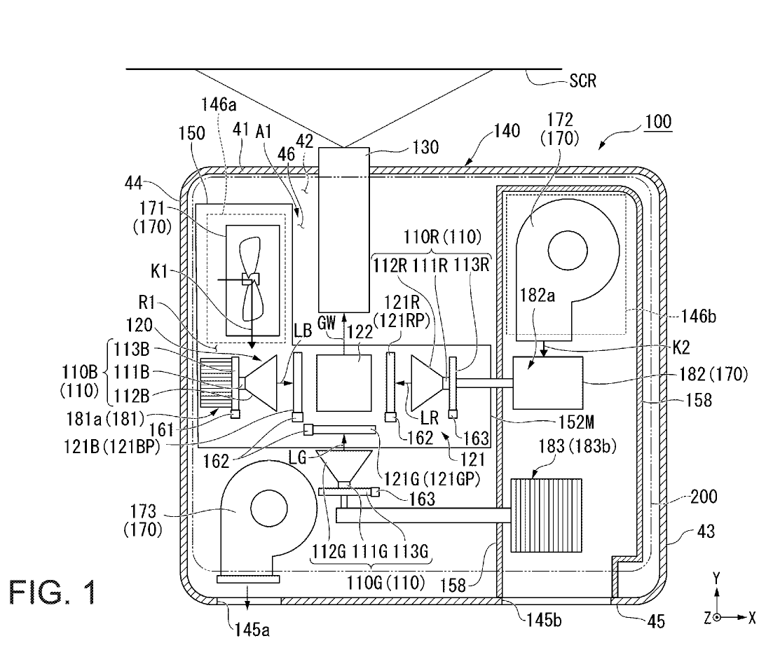

FIG. 1 is a schematic configuration diagram of a projector according to the present embodiment.

A projector 100 according to the present embodiment includes a light source device 110, an image forming device 120, a projection optical device 130, an outer housing 140, and a cooling device 170, as illustrated in FIG. 1.

Hereinafter, an arrangement relationship of each member may be described using an XYZ coordinate system illustrated in the drawings. In each drawing, a Y-axis is an axis along a direction in which the projector 100 projects an image. An X-axis is an axis orthogonal to the Y-axis and is an axis along a width direction of a screen SCR that is a projected surface on which an image is projected. A Z-axis is an axis orthogonal to the X-axis and the Y-axis, and is an axis along a normal line of an installation surface on which the projector 100 is installed.

In the present embodiment, for example, both directions along the Z-axis are collectively referred to as "vertical direction Z" in the projector 100, and a direction toward a +Z direction is referred to as "upper side" and a direction toward a -Z direction is referred to as "lower side". Both directions along the X-axis are collectively referred to as "left-right direction X" in the projector 100, and a direction toward a +X direction is referred to as "right side" and a direction toward a -X direction is referred to as "left side". Both directions along the Y-axis may be collectively referred to as "front-rear direction Y" in the projector 100, and a direction toward a +Y direction may be referred to as "front side" and a direction toward a -Y direction may be referred to as "rear side".

In the present embodiment, the vertical direction Z, the front-rear direction Y, and the left-right direction X are simply names for describing an arrangement relationship of the respective component members of the projector 100, and do not define the actual installation posture or orientation in the projector 100.

The outer housing 140 is a box-shaped member having a substantially rectangular parallelepiped shape and a hollow inside. The outer housing 140 accommodates the light source device 110, the image forming device 120, the projection optical device 130, the cooling device 170, and a circuit substrate 200.

The outer housing 140 includes a front side wall section 41, a top wall section 42, a right side wall section 43, a left side wall section 44, a rear side wall section 45, and a bottom wall section 46. In FIG. 1, the top wall section 42 is illustrated as a transparent member in order to illustrate an internal structure of the outer housing 140.

In the outer housing 140, the front side wall section 41 is a plate material positioned in the +Y direction, which is a front side in the front-rear direction Y, the top wall section 42 is a plate material positioned in the +Z direction, which is an upper side in the vertical direction Z, the right side wall section 43 is a plate material positioned in the +X direction, which is a right side in the left-right direction X, the left side wall section 44 is a plate material positioned in the -X direction, which is a left side in the left-right direction X, the rear side wall section 45 is a plate material positioned in the -Y direction, which is a rear side in the front-rear direction Y, and the bottom wall section 46 is a plate material positioned in the -Z direction, which is a lower side in the vertical direction Z.

The front side wall section 41 is a wall section facing the screen SCR, which is the projected surface on which an image is projected from the projector 100. The front side wall section 41 and the rear side wall section 45 are arranged parallel to an XZ plane and are arranged so as to face each other. The rear side wall section 45 faces an opposite side to the front side wall section 41 in the front-rear direction Y along the Y-axis.

The right side wall section 43 and the left side wall section 44 are arranged parallel to a YZ plane and are arranged so as to face each other. The right side wall section 43 and the left side wall section 44 face opposite sides to each other in the left-right direction X along the X-axis orthogonal to the Y-axis.

The top wall section 42 and the bottom wall section 46 are arranged parallel to an XY plane and are arranged so as to face each other. The top wall section 42 and the bottom wall section 46 face opposite sides to each other in the vertical direction Z along the Z-axis orthogonal to the X-axis and the Y-axis.

The projector 100 according to the present embodiment is installed in a state in which the bottom wall section 46 of the outer housing 140 faces a projector installation surface, for example, a table upper surface. That is, the top wall section 42 is positioned on an opposite side of the bottom wall section 46 facing the projector installation surface.

The front side wall section 41, the right side wall section 43, the left side wall section 44 and the top wall section 42 are arranged to intersect with each other, specifically, to be orthogonal to each other. The front side wall section 41, the right side wall section 43, the left side wall section 44 and the bottom wall section 46 are arranged to intersect with each other, specifically, to be orthogonal to each other.

The light source device 110 includes a blue light source (first light source) 110B that emits blue light LB, a red light source (second light source) 110R that emits red light LR, and a green light source (third light source) 110G that emits green light LG.

The blue light source 110B includes a blue light emitter 111B that emits the blue light (first light) LB having a blue wavelength band of, for example, 420nm to 500nm as a first wavelength band, and a blue light collimating element 112B that collimates the blue light LB. The blue light emitter 111B is supported by a first substrate 113B.

The red light source 110R includes a red light emitter 111R that emits the red light (second light) LR having a red wavelength band of, for example, 610nm to 700nm as a second wavelength band different from the first wavelength band, and a red light collimating element 112R that collimates the red light LR. The red light emitter 111R is supported by a second substrate 113R.

The green light source 110G includes a green light emitter 111G that emits the green light (third light) LG having a green wavelength band of, for example, 500nm to 600nm as a third wavelength band different from the first wavelength band and the second wavelength band, and a green light collimating element 112G that collimates the green light LG. The green light emitter 111G is supported by a third substrate 113G.

The image forming device 120 forms image light from light emitted from the light source device 110. The image forming device 120 includes a light modulation section that modulates light incident from the light source device 110 based on image information.

Specifically, the image forming device 120 according to the present embodiment includes a light modulation section 121 including a blue light modulation element 121B, a green light modulation element 121G, and a red light modulation element 121R, and a light combining optical system 122.

The blue light modulation element 121B is composed of a liquid crystal panel 121BP and polarizing plates (not illustrated) provided on an incident side and an emission side of the liquid crystal panel 121BP. The blue light modulation element 121B modulates the blue light LB incident from the blue light source 110B in accordance with an image signal to generate blue image light.

The green light modulation element 121G is composed of a liquid crystal panel 121GP and polarizing plates (not illustrated) provided on an incident side and an emission side of the liquid crystal panel 121GP. The green light modulation element 121G modulates the green light LG incident from the green light source 110G in accordance with an image signal to generate green image light.

The red light modulation element 121R is composed of a liquid crystal panel 121RP and polarizing plates (not illustrated) provided on an incident side and an emission side of the liquid crystal panel 121RP. The red light modulation element 121R modulates the red light LR incident from the red light source 110R in accordance with an image signal to generate red image light.

The light combining optical system 122 is composed of a substantially cubic cross dichroic prism. The light combining optical system 122 generates full-color image light GW obtained by combining image light of respective colors from the light modulation elements 121B, 121G, and 121R. In this way, the image forming device 120 emits the combined full-color image light toward the projection optical device 130.

The projection optical device 130 enlarges and projects the image light GW emitted from the image forming device 120 toward the screen SCR. The projection optical device 130 projects light to display an enlarged color image on the screen SCR. The projection optical device 130 includes a plurality of projection lenses (not illustrated). The number of projection lenses constituting the projection optical device 130 is not limited.

In the present embodiment, the projection optical device 130 is arranged in the front side wall section 41 of the outer housing 140. In the present embodiment, a distal end surface of the projection optical device 130 protrudes from a surface of the front side wall section 41 of the outer housing 140, but may be flush with or positioned inside the surface of the front side wall section 41 of the outer housing 140.

The projector 100 according to the present embodiment accommodates a heat generating member that generates heat when driven inside the outer housing 140. Examples of the heat generating member according to the present embodiment include the light sources 110B, 110G, and 110R of respective colors of the light source device 110 and the light modulation section 121 of the image forming device 120.

The cooling device 170 cools the light source device 110 and the image forming device 120 including the above-described heat generating member. In the projector 100 according to the present embodiment, the inside of the outer housing 140 is partitioned into two regions, namely a first region A1 and a second region A2. The first region A1 and the second region A2 are arranged in the left-right direction X inside the outer housing 140, and each extend in the front-rear direction Y. A first cooling flow path R1 (to be described later) is provided in the first region A1, and a second cooling flow path R2 (to be described later) is provided in the second region A2.

The circuit substrate 200 is formed in a substantially rectangular shape when viewed in plan in the vertical direction Z. The circuit substrate 200 is arranged in the outer housing 140 so as to cover the first region A1 and the second region A2 from an upper side (+Z side). The circuit substrate 200 includes a system on a chip (SoC) 201, which is an example of an integrated circuit element, and controls driving of the light source device 110, the image forming device 120, and the cooling device 170. The circuit substrate 200 is electrically connected to the light source device 110, the image forming device 120, and the cooling device 170. A mounting surface of the circuit substrate 200 on which the SoC 201 is mounted faces the inside (-Z side) of the outer housing 140.

The projector 100 according to the present embodiment further includes a first detection section 161, a second detection section 162, and a third detection section 163.

The first detection section 161 detects temperature information of the blue light source 110B. The first detection section 161 according to the present embodiment is, for example, a thermistor mounted on the first substrate 113B that supports the blue light emitter 111B of the blue light source 110B. In this manner, the first detection section 161 detects a temperature of the blue light emitter 111B as temperature information of the blue light source 110B.

The second detection section 162 detects temperature information of the image forming device 120. The second detection section 162 according to the present embodiment detects temperatures of the liquid crystal panels 121BP, 121GP, and 121RP of the light modulation elements 121B, 121G, and 121R. The second detection section 162 according to the present embodiment is configured by three thermistors corresponding to the liquid crystal panels 121BP, 121GP, and 121RP. In this manner, the second detection section 162 detects temperatures of the liquid crystal panels 121BP, 121GP, and 121RP as a temperature of the image forming device 120. The second detection section 162 may be configured to acquire ambient temperatures of the three liquid crystal panels as a panel average temperature by one thermistor provided in common to the liquid crystal panels 121BP, 121GP, and 121RP.

The third detection section 163 detects temperature information of the red light source 110R and the green light source 110G. The third detection section 163 according to the present embodiment is, for example, a thermistor mounted on the second substrate 113R that supports the red light emitter 111R of the red light source 110R, and a thermistor mounted on the third substrate 113G that supports the green light emitter 111G of the green light source 110G. In this way, the third detection section 163 detects temperatures of the red light emitter 111R and the green light emitter 111G as temperature information of the red light source 110R and the green light source 110G.

The first detection section 161, the second detection section 162, and the third detection section 163 are electrically connected to the circuit substrate 200, and output respective detection results to the circuit substrate 200. The circuit substrate 200 controls the driving of the cooling device 170 based on temperature information acquired from the first detection section 161, the second detection section 162, and the third detection section 163.

The cooling device 170 includes a first fan 171, a second fan 172, an exhaust fan 173, a duct member 150, a partition member 158, a first heat dissipator 181, a second heat dissipator 182, and a third heat dissipator 183.

The cooling device 170 controls the driving of the first fan 171 based on detection results of the first detection section 161 and the second detection section 162. Specifically, the cooling device 170 according to the present embodiment adjusts an air-flow amount of the first fan 171 based on temperature information of the image forming device 120 and temperature information of the blue light source 110B. Note that the exhaust fan 173 may operate in conjunction with the driving of the first fan 171, and the exhaust fan 173 may also independently adjust an air-flow amount based on temperature information of the image forming device 120 and temperature information of the blue light source 110B.

The cooling device 170 controls the driving of the second fan 172 based on a detection result of the third detection section 163. Specifically, the cooling device 170 according to the present embodiment adjusts an air-flow amount of the second fan 172 based on temperature information of the red light source 110R and the green light source 110G.

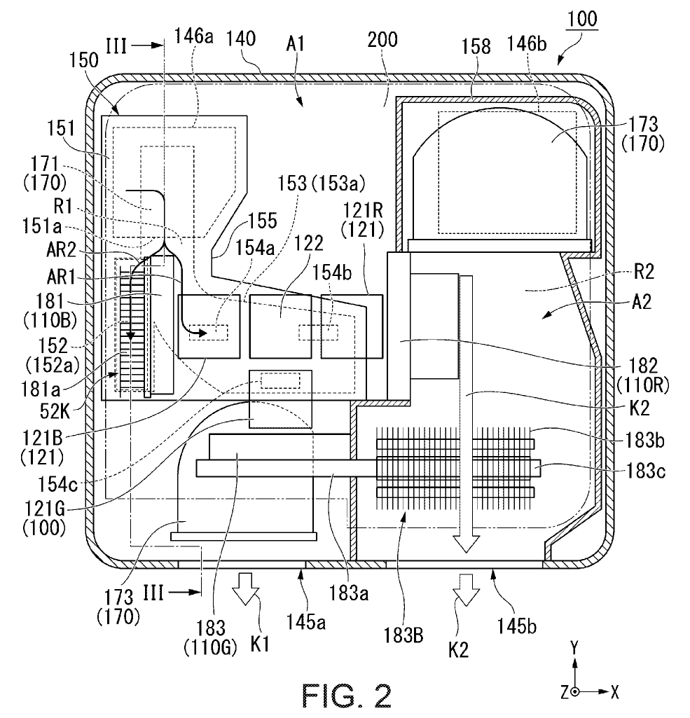

Hereinafter, a configuration of the cooling device 170 will be described in detail. FIG. 2 is a diagram illustrating a cooling configuration of the projector 100.

As illustrated in FIGS. 1 and 2, the first heat dissipator 181 is thermally connected to the blue light source 110B. The first heat dissipator 181 according to the present embodiment includes a heat sink provided on the first substrate 113B of the blue light source 110B on a side opposite to a support surface of the blue light emitter 111B. In the first heat dissipator 181, a plurality of first heat dissipation fins 181a formed of metal plates extending parallel to the XZ plane are provided with gaps therebetween in the Y direction.

The blue light emitter 111B of the blue light source 110B, which is thermally connected to the first heat dissipator 181, has less heating amount than the green light emitter 111G of the green light source 110G and the red light emitter 111R of the red light source 110R. That is, the blue light emitter 111B has a smallest heating amount among the light emitters of three colors.

The second heat dissipator 182 is thermally connected to the red light source 110R. The second heat dissipator 182 according to the present embodiment includes a heat sink provided on the second substrate 113R of the red light source 110R on a side opposite to a support surface of the red light emitter 111R. In the second heat dissipator 182, a plurality of second heat dissipation fins 182a formed of metal plates extending parallel to the XY plane are provided with gaps therebetween in the Z direction.

The red light emitter 111R of the red light source 110R, which is thermally connected to the second heat dissipator 182, has a lowest management temperature among the light emitters of three colors. The red light emitter 111R of the red light source 110R has a smaller heating amount and a larger variation in light emitting characteristics with respect to a temperature than the green light emitter 111G of the green light source 110G. That is, when a temperature of the red light emitter 111R is out of a predetermined temperature due to heat generation, a light emission amount greatly varies, and it becomes difficult to obtain a desired light emission amount. Therefore, in order to stabilize light emitting characteristics of the red light emitter 111R, it is necessary to perform temperature management so that a temperature is maintained lower than that of the light emitters of other colors. In other words, it is more difficult to manage a temperature of the red light source 110R than that of the light sources of other colors.

The third heat dissipator 183 is thermally connected to the green light source 110G. The third heat dissipator 183 according to the present embodiment includes a heat pipe 183a and cooling fins 183b. The heat pipe 183a has a shaft shape extending in left-right direction X, and is provided via grease on a side of third substrate 113G of green light source 110G opposite to the support surface of green light emitter 111G. The heat pipe 183a extends from the first cooling flow path R1 to the second cooling flow path R2 through the partition member 158.

The cooling fins 183b are formed by providing a plurality of metal plates extending parallel to the YZ plane with gaps in the left-right direction X. The plurality of metal plates constituting the cooling fins 183b are connected by a cylinder section 183c extending in the left-right direction X. The cooling fins 183b are provided on the heat pipe 183a drawn out from the first region A1 including the first cooling flow path R1 to the second cooling flow path R2 of the second region A2. The heat pipe 183a is inserted into the cylinder section 183c from a left side (-X side) and comes into contact with the cylinder section 183c. That is, the heat pipe 183a is arranged across the first region A1 and the second region A2 by penetrating the partition member 158, and are in contact with the green light source 110G and the cooling fins 183b.

Here, the green light emitter 111G of the green light source 110G thermally connected to the third heat dissipator 183 has a largest heating amount among the light emitters of three colors. The green light emitter 111G of the green light source 110G has a relatively high management temperature among the light emitters of three colors, and has a leeway in temperature management at least as compared with the red light emitter 111R.

In the cooling device 170 according to the present embodiment, among the first heat dissipator 181, the second heat dissipator 182, and the third heat dissipator 183, the first heat dissipation fins 181a of the first heat dissipator 181 thermally connected to the blue light emitter 111B having a smallest heating amount has a smallest surface area and a narrowest arrangement pitch. That is, since the first heat dissipator 181 is the smallest among the first heat dissipator 181, the second heat dissipator 182, and the third heat dissipator 183, it is possible to prevent a device configuration from becoming large in size in a case of arranging the first heat dissipator 181 in the vicinity of the blue light source 110B.

As illustrated in FIG. 1, the first fan 171 takes in cooling air K1 into the duct member 150 provided inside the outer housing 140 via a first intake port 146a provided in the bottom wall section 46 of the outer housing 140. The first fan 171 is, for example, a centrifugal fan that rotates about a rotation shaft extending in the left-right direction X.

The exhaust fan 173 is arranged to face the rear side wall section 45. The rear side wall section 45 includes a first exhaust port 145a at a position facing the exhaust fan 173.

The exhaust fan 173 is, for example, a centrifugal fan that rotates about a rotation shaft extending in the vertical direction Z. The exhaust fan 173 is driven in conjunction with the first fan 171, and blows drawn air to a rear side (-Y side) to exhaust the air from the first exhaust port 145a. The exhaust fan 173 may be linked to temperature information of the image forming device 120 and temperature information of the blue light source 110B.

The duct member 150 forms the first cooling flow path R1 in the first region A1 in the outer housing 140. The first cooling flow path R1 is a flow path for supplying the cooling air K1 to the blue light source 110B and the light modulation section 121. The duct member 150 includes a fan case 151 that accommodates the first fan 171, and a branch section 155 that branches a flow of the cooling air K1 drawn by the first fan 171.

The fan case 151 accommodates the first fan 171 and is open at a position facing the bottom wall section 46. The bottom wall section 46 includes the first intake port 146a on a surface facing the fan case 151. The first fan 171 takes in the cooling air K1 into the duct member 150 through the first intake port 146a provided in the bottom wall section 46. The fan case 151 is provided with a discharge port 151a at a position facing a discharge port of the first fan 171.

The branch section 155 is connected to the discharge port 151a of the fan case 151. The branch section 155 branches into a first path 152a that guides a part of the cooling air K1 to the blue light source 110B and a second path 153a that guides the remaining part of the cooling air K1 to the light modulation section 121.

The branch section 155 includes a first duct 152 that forms the first path 152a therein and a second duct 153 that forms the second path 153a therein. The first duct 152 and the second duct 153 include respective bases joined together and respective distal ends extending in a predetermined direction.

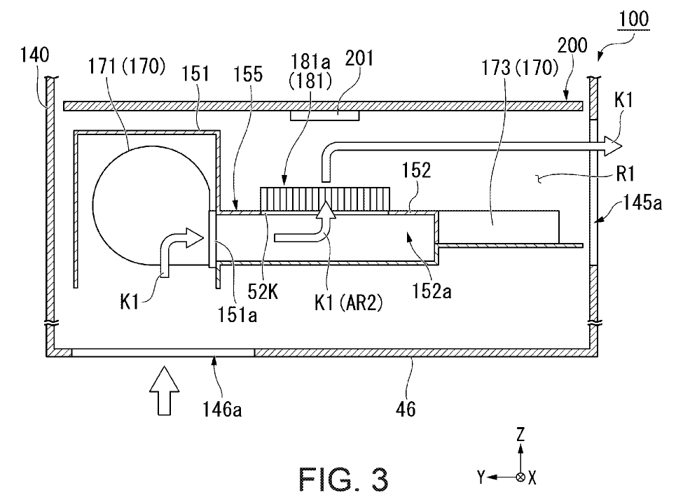

FIG. 3 is a cross-sectional view taken along line III-III in FIG. 2.

As illustrated in FIG. 3, the first duct 152 extends from the discharge port 151a to a lower side of the first heat dissipator 181, and includes an opening section 52K facing the first heat dissipator 181 in the vertical direction Z.

The second duct 153 extends from the discharge port 151a to a position overlapping the light modulation section 121 and the light combining optical system 122, and includes a first opening 154a, a second opening 154b, and a third opening 154c facing the blue light modulation element 121B, the green light modulation element 121G, and the red light modulation element 121R of the light modulation section 121 in the vertical direction Z. The first opening 154a is open at a position overlapping the blue light modulation element 121B in the vertical direction Z. The second opening 154b is open at a position overlapping the red light modulation element 121R and the light combining optical system 122 in the vertical direction Z. The third opening 154c is open at a position overlapping the green light modulation element 121G in the vertical direction Z.

Among air taken in by the first fan 171 through the first intake port 146a and blown to the branch section 155, the cooling air K1 blown from the opening section 52K of the first duct 152 passes through the first heat dissipator 181, cools the first heat dissipator 181 by heat exchange, and is then blown toward the circuit substrate 200.

The first heat dissipator 181 guides the cooling air K1 that passed via the first path 152a to the circuit substrate 200 arranged on an upper side (+Z side) of the duct member 150. The cooling air K1 blown toward the circuit substrate 200 flows along a lower side (-Z side) surface of the circuit substrate 200, thereby efficiently cooling the circuit substrate 200. The cooling air K1 that exchanged heat with the circuit substrate 200 is drawn into the exhaust fan 173 and then exhausted from the first exhaust port 145a.

In addition, among air drawn by the first fan 171 through the first intake port 146a and blown to the branch section 155, the cooling air K1 blown from the first opening 154a of the second duct 153 is blown toward the blue light modulation element 121B, cools the blue light modulation element 121B by heat exchange, and is then blown toward the circuit substrate 200.

The cooling air K1 blown from the second opening 154b of the second duct 153 is blown toward the red light modulation element 121R, cools the red light modulation element 121R by heat exchange, and is then blown toward the circuit substrate 200.

The cooling air K1 blown from the third opening 154c of the second duct 153 is blown toward the green light modulation element 121G, cools the green light modulation element 121G by heat exchange, and is then blown toward the circuit substrate 200.

As described above, in the cooling device 170 according to the present embodiment, the duct member 150 guides the cooling air K1 that cooled the blue light source 110B via the first path 152a of the first duct 152 and the cooling air K1 that cooled the light modulation section 121 via the second path 153a of the second duct 153 to the circuit substrate 200. This makes it possible to cool the circuit substrate 200, and thus to efficiently cool the SoC 201.

As illustrated in FIG. 2, in the cooling device 170 according to the present embodiment, in the first cooling flow path R1, an air-flow amount AR1 of the cooling air K1 in the second path 153a is larger than an air-flow amount AR2 of the cooling air K1 in the first path 152a. Specifically, the cooling device 170 configures drive conditions of the first fan 171 and the exhaust fan 173, or a length and internal shape of the duct member 150, so that the air-flow amount AR1 in the second path 153a is larger than the air-flow amount AR2 in the first path 152a. By this, the cooling device 170 can increase cooling performance of the second path 153a more than cooling performance of the first path 152a.

The first cooling flow path R1 efficiently supplies the cooling air K1 to the light modulation section 121, which requires higher cooling performance than the blue light source 110B, and therefore the light modulation elements 121B, 121G, and 121R of the light modulation section 121 can be efficiently cooled. Therefore, it is possible to prevent deterioration or damage due to heat in the respective light modulation elements 121B, 121G, and 121R.

The cooling device 170 according to the present embodiment controls the first fan 171, which blows air to the first cooling flow path R1, which cools the light modulation section 121 and the blue light source 110B of the image forming device 120, by using temperature information on the image forming device 120 and the blue light source 110B, which is a part of the light source device 110. Therefore, the cooling device 170 uses temperature information of the blue light source 110B in addition to temperature information of the image forming device 120, and thus can control an air-flow amount of the cooling air K1 by the first fan 171 with high accuracy.

As described above, when controlling the first fan 171, the cooling device 170 uses temperature information of the blue light source 110B, which is not a light source having a largest heating amount and is not a light source having a lowest management temperature in the light source device 110 and has a leeway for temperature management, and thus, for example, compared to a case where temperature information of the red light source 110R, which has no leeway for temperature management and requires precise control so as not to exceed a predetermined temperature, is used, the control of the first fan 171 can be simplified.

In the cooling device 170 according to the present embodiment, as illustrated in FIGS. 1 and 2, the second fan 172 takes the cooling air K2 into the second cooling flow path R2 partitioned by the partition member 158 provided inside the outer housing 140 through the second intake port 146b provided in the bottom wall section 46 of the outer housing 140. The second fan 172 is, for example, a centrifugal fan that rotates about a rotation shaft extending in the vertical direction Z. The second fan 172 blows air drawn into the partition member 158 from the second intake port 146b to a rear side (-Y side) and exhausts the air from a second exhaust port 145b, thereby blowing the cooling air K2 toward the second heat dissipator 182 and the third heat dissipator 183 in the second cooling flow path R2.

The second fan 172 adjusts an air-flow amount based on temperature information of the red light source 110R and the green light source 110G as described above. By providing the second fan 172, the cooling device 170 can improve cooling performance of the red light source 110R and the green light source 110G.

Here, temperature management of the red light source 110R, which is thermally connected to the second heat dissipator 182, is more difficult than that of the green light source 110G, which is thermally connected to the third heat dissipator 183. Therefore, the red light emitter 111R of the red light source 110R has a smaller heating amount and a larger variation in light emitting characteristics with respect to a temperature than the green light emitter 111G of the green light source 110G. Therefore, when a temperature of the red light emitter 111R is out of a predetermined temperature due to heat generation, a light emission amount greatly varies, and it is difficult to obtain a desired light emission amount, and it is difficult to manage a temperature of the red light emitter 111R as compared with other light emitters.

In the cooling device 170 according to the present embodiment, the second heat dissipator 182 is arranged at a position closer to the second fan 172, which is on an upstream side of the cooling air K2, than the third heat dissipator 183. Therefore, the second fan 172 can preferentially supply the cooling air K2, which is taken in through the second intake port 146b and has a relatively low temperature close to an ambient temperature, to the second heat dissipator 182.

As the second heat dissipator 182 is cooled, the red light emitter 111R of the red light source 110R is cooled via the second substrate 113R. In this way, since the second heat dissipator 182 is cooled by heat exchange with the relatively low-temperature cooling air K2 blown to the second cooling flow path R2, the red light emitter 111R of the red light source 110R is efficiently cooled, so that a temperature of the red light source 110R can be stably managed.

On the other hand, a temperature of the green light emitter 111G of the green light source 110G is relatively easily managed compared to the red light emitter 111R. That is, the green light emitter 111G has a larger heating amount and has a smaller variation in light emitting characteristics with respect to a temperature than the red light emitter 111R. Therefore, the green light emitter 111G is less likely to vary in a light emission amount even when heat is generated, compared to the red light emitter 111R.

As described above, the red light emitter 111R has less heating amount than the green light emitter 111G. Therefore, the temperature rise of the cooling air K2 after heat exchange with the second heat dissipator 182 thermally connected to the red light emitter 111R is prevented. Therefore, the third heat dissipator 183 is supplied with the relatively low-temperature cooling air K2.

As a temperature of the heat pipe 183a rises due to the heat pipe 183a being in contact with the third substrate 113G, working liquid of the heat pipe 183a vaporizes on a side in contact with the third substrate 113G and turns into gas, and the third heat dissipator 183 absorbs heat from the third substrate 113G by latent heat of vaporization at this time. The gas in the heat pipe 183a is condensed and returns to liquid as the cooling fins 183b are cooled, and returns to a third substrate 113G side. In this way, the green light emitter 111G of the green light source 110G is indirectly cooled via the heat pipe 183a by heat exchange between the cooling fins 183b and the cooling air K2 flowing through the second cooling flow path R2.

In the cooling device 170 according to the present embodiment, a surface area of the third heat dissipator 183 is sufficiently enlarged by providing the cooling fins 183b on the heat pipe 183a drawn out over substantially the entire width of the second cooling flow path R2 in the left-right direction X, and thus heat dissipation performance can be enhanced.

Therefore, the third heat dissipator 183 can sufficiently cool the green light emitter 111G of green light source 110G even in heat exchange with the cooling air K2 that was warmed by heat exchange with the second heat dissipator 182. Therefore, a temperature of the green light source 110G can be stably managed by cooling the green light emitter 111G.

As described above, the projector 100 according to the present embodiment includes the light source device 110, the image forming device 120 that forms image light from light emitted from the light source device 110, the projection optical device 130 that projects the image light emitted from the image forming device 120, and the cooling device 170 that cools the light source device 110 and the image forming device 120. The light source device 110 includes the blue light source 110B that emits the blue light LB, the red light source 110R that emits the red light LR, and the green light source 110G that emits the green light LG. The image forming device 120 includes the light modulation section 121 that modulates light incident from the light source device 110 based on image information. The cooling device 170 includes the first fan 171 that supplies the cooling air K1 to the blue light source 110B and the light modulation section 121. A heating amount of the blue light source 110B is smaller than a heating amount of the red light source 110R and a heating amount of the green light source 110G, and among the blue light source 110B, the red light source 110R, and the green light source 110G, the green light source 110G has a largest heating amount and the red light source 110R has a lowest management temperature. The cooling device 170 adjusts at least one of an air-flow amount and an air flow of the cooling air K1 by at least one of the first fan 171 and the exhaust fan 173 based on temperature information of the image forming device 120 and temperature information of the blue light source 110B.

According to the projector 100 according to the present embodiment, since temperature information of the blue light source 110B is also used in addition to temperature information of the image forming device 120, it is possible to perform the control of the cooling air K1 by at least one of the first fan 171 and the exhaust fan 173 with high accuracy. Since the cooling device 170 according to the present embodiment uses temperature information of the blue light source 110B, which is not a light source having a largest heating amount and not a light source having a lowest management temperature among the light source devices 110, and which has a leeway for temperature management, it is possible to simplify the control of at least one of the first fan 171 and the exhaust fan 173 compared to a case of using temperature information of the red light source 110R, which has no leeway for temperature management and requires precise temperature control, for example. Since the first fan 171 supplies the cooling air K1 to the blue light source 110B and the light modulation section 121, it is possible to prevent an increase in the size of a device configuration compared with a configuration in which the blue light source 110B and the light modulation section 121 are individually provided with cooling fans.

Therefore, according to the present embodiment, it is possible to provide the projector 100 excellent in cooling performance while preventing the increase in the size of a device configuration and the complication of the control.

The technical scope of the present disclosure is not limited to the above-described embodiment, and various modifications can be made without departing from the spirit of the present disclosure.

In the projector according to the above-described embodiment, there is cited a case of controlling an air-flow amount of the first fan using temperature information of the first light source having a leeway in temperature management, which is not a light source having a largest heating amount and is not a light source having a lowest management temperature, among the three light sources of the light source device, but the disclosure is not limited to this.

For example, the disclosure can also be applied to a projector that controls an air-flow amount of one or a plurality of fans using temperature information of a circuit component that has a leeway for temperature management, that is, a circuit component that is not a circuit component having a largest heating amount and that is not a circuit component having a lowest management temperature among three circuit components of the circuit substrate.

In this case, the projector according to the disclosure includes a light source device, an image forming device that forms the image light from light emitted from the light source device, a circuit substrate that controls the light source device and the image forming device, a projection optical device that projects the image light emitted from the image forming device, and a cooling device that cools the circuit substrate and the image forming device, and the circuit substrate includes a first circuit component, a second circuit component, and a third circuit component. The image forming device includes a light modulation section that modulates light incident from the light source device based on image information, the cooling device includes a first fan that supplies cooling air to the first circuit component and the light modulation section, a heating amount of the first circuit component is less than a heating amount of the second circuit component and a heating amount of the third circuit component, among the first circuit component, the second circuit component, and the third circuit component, the third circuit component has a highest heating amount and the second circuit component has a lowest management temperature, and the cooling device is configured to adjust an air-flow amount of the cooling air by the first fan based on temperature information of the image forming device and temperature information of the first circuit component.

According to the projector having this configuration, since temperature information of the first circuit component that is not a circuit component having a largest heating amount and is not a circuit component having a lowest management temperature and has a leeway in temperature management is used, for example, compared to a case where temperature information of the second circuit component that has no leeway in temperature management and requires precise temperature control is used, the control of the first fan can be simplified. Since the first fan supplies the cooling air to the first circuit component and the light modulation section, it is possible to prevent an increase in the size of a device configuration compared with a configuration in which the first circuit component and the light modulation section are individually provided with cooling fans.

Therefore, according to the present embodiment, it is possible to provide the projector 100 excellent in cooling performance while preventing the increase in the size of a device configuration and the complication of the control.

### Summary of Present Disclosure

Hereinafter, a summary of the present disclosure is appended.

First note

A projector includes

a light source device;

an image forming device that forms image light from light emitted from the light source device;

a projection optical device that projects the image light emitted from the image forming device; and

a cooling device that cools the light source device and the image forming device, wherein

the light source device includes

a first light source that emits first light in a first wavelength band,

a second light source that emits second light in a second wavelength band different from the first wavelength band, and

a third light source that emits third light in a third wavelength band different from the first wavelength band and the second wavelength band,

the image forming device includes a light modulation section that modulates light incident from the light source device based on image information,

the cooling device includes a first fan that supplies cooling air to the first light source and the light modulation section,

a heating amount of the first light source is smaller than a heating amount of the second light source and a heating amount of the third light source,

among the first light source, the second light source, and the third light source, the third light source has a largest heating amount and the second light source has a lowest management temperature, and

the cooling device adjusts an air-flow amount of the cooling air by the first fan based on temperature information of the image forming device and temperature information of the first light source.

According to the projector including this configuration, since temperature information of the first light source is also used in addition to temperature information of the image forming device, it is possible to perform the air-flow amount control of the cooling air by the first fan with high accuracy. The cooling device including this configuration uses temperature information of the first light source having a leeway for temperature management, which is not a light source having a largest heating amount and is not a light source having a lowest management temperature, in the light source device, and thus, for example, compared to a case where temperature information of the second light source having no leeway for temperature management and requiring precise temperature control is used, the control of the first fan can be simplified. Since the first fan supplies the cooling air to the first light source and the light modulation section, it is possible to prevent a device configuration from becoming larger in size compared to a configuration in which the first light source and the light modulation section are individually provided with cooling fans.

Therefore, according to this configuration, it is possible to provide a projector having excellent cooling performance while preventing the increase in the size of a device configuration and the complication of the control.

Second note

The projector according to first note, wherein

the cooling device further includes

a first heat dissipator thermally connected to the first light source,

a second heat dissipator thermally connected to the second light source, and

a third heat dissipator thermally connected to the third light source and

among the first heat dissipator, the second heat dissipator, and the third heat dissipator, heat dissipation fins in the first heat dissipator have a smallest surface area and a narrowest arrangement pitch.

According to this configuration, the first heat dissipator is the smallest among the first heat dissipator, the second heat dissipator, and the third heat dissipator, and thus, it is possible to prevent the increase in the size of a device configuration in a case where the first heat dissipator is arranged in the vicinity of the first light source.

Third note

The projector according to second note, wherein

the cooling device further includes a second fan that supplies cooling air to the second heat dissipator and the third heat dissipator.

According to this configuration, the second fan is provided, and thus it is possible to improve cooling performance of the second light source and the third light source.

Fourth note

The projector according to any one of first note to third note, wherein

the cooling device further includes a duct member that guides the cooling air from the first fan,

the duct member includes a branch section that branches the cooling air into a first path that guides the cooling air to the first light source and a second path that guides the cooling air to the light modulation section, and

an air-flow amount of the cooling air in the second path is larger than an air-flow amount of the cooling air in the first path.

According to this configuration, since the duct member efficiently supplies the cooling air to the light modulation section having a higher required cooling capacity than the first light source, it is possible to efficiently cool the light modulation section. Therefore, it is possible to prevent deterioration or damage of the light modulation section due to heat.

Fifth note

The projector according to fourth note further includes

a circuit substrate that controls at least the light source device and the image forming device, wherein

the duct member guides the cooling air that cooled the first light source via the first path and the cooling air that cooled the light modulation section via the second path to the circuit substrate.

According to this configuration, the duct member guides the cooling air that cooled the first light source via the first path and the cooling air that cooled the light modulation section via the second path to the circuit substrate, and thus, for example, a circuit component that is mounted on the circuit substrate and needs to be cooled can be efficiently cooled.

Sixth note

The projector according to fifth note, wherein

the cooling device includes a first heat dissipator thermally connected to the first light source and

the first heat dissipator guides the cooling air that passed via the first path to the circuit substrate.

According to this configuration, the cooling efficiency of the circuit substrate can be enhanced by using the cooling air that passed via the first path.

Seventh note

The projector according to any one of first note to sixth note further includes

a first detection section that detects a temperature of the first light source and

a second detection section that detects a temperature of the image forming device, wherein

the cooling device controls the first fan based on detection results of the first detection section and the second detection section.

According to this configuration, the first fan can be controlled with higher accuracy based on detection values of temperatures of the first light source and the image forming device.

Eighth note

A projector includes

a light source device;

an image forming device that forms image light from light emitted from the light source device;

a circuit substrate that controls the light source device and the image forming device;

a projection optical device that projects the image light emitted from the image forming device; and

a cooling device that cools the circuit substrate and the image forming device, wherein

the circuit substrate includes a first circuit component, a second circuit component, and a third circuit component,

the image forming device includes a light modulation section that modulates light incident from the light source device based on image information,

the cooling device includes a first fan that supplies cooling air to the first circuit component and the light modulation section,

a heating amount of the first circuit component is less than a heating amount of the second circuit component and a heating amount of the third circuit component,

among the first circuit component, the second circuit component, and the third circuit component, the third circuit component has a highest heating amount and the second circuit component has a lowest management temperature, and

the cooling device adjusts an air-flow amount of the cooling air by the first fan based on temperature information of the image forming device and temperature information of the first circuit component.

According to the projector having this configuration, since temperature information of the first circuit component that is not a circuit component having a largest heating amount and is not a circuit component having a lowest management temperature and has a leeway in temperature management is used, for example, compared to a case where temperature information of the second circuit component that has no leeway in temperature management and requires precise temperature control is used, the control of the first fan can be simplified. Since the first fan supplies the cooling air to the first circuit component and the light modulation section, it is possible to prevent an increase in the size of a device configuration compared with a configuration in which the first circuit component and the light modulation section are individually provided with cooling fans.

Therefore, according to this configuration, it is possible to provide a projector having excellent cooling performance while preventing then increase in the size of a device configuration and the complication of the control.

What is claimed is:

1. A projector comprising:
a light source device;
an image forming device that forms image light from light emitted from the light source device;
a projection optical device that projects the image light emitted from the image forming device; and
a cooling device that cools the light source device and the image forming device, wherein
the light source device includes
a first light source that emits first light in a first wavelength band,
a second light source that emits second light in a second wavelength band different from the first wavelength band, and
a third light source that emits third light in a third wavelength band different from the first wavelength band and the second wavelength band,
the image forming device includes a light modulation section that modulates light incident from the light source device based on image information,
the cooling device includes a first fan that supplies cooling air to the first light source and the light modulation section,
a heating amount of the first light source is smaller than a heating amount of the second light source and a heating amount of the third light source,
among the first light source, the second light source, and the third light source, the third light source has a largest heating amount and the second light source has a lowest management temperature, and
the cooling device adjusts an air-flow amount of the cooling air by the first fan based on temperature information of the image forming device and temperature information of the first light source.

2. The projector according to claim 1, wherein
the cooling device further includes
a first heat dissipator thermally connected to the first light source,
a second heat dissipator thermally connected to the second light source, and
a third heat dissipator thermally connected to the third light source and
among the first heat dissipator, the second heat dissipator, and the third heat dissipator, heat dissipation fins in the first heat dissipator have a smallest surface area and a narrowest arrangement pitch.

3. The projector according to claim 2, wherein
the cooling device further includes a second fan that supplies cooling air to the second heat dissipator and the third heat dissipator.

4. The projector according to claim 1, wherein
the cooling device further includes a duct member that guides the cooling air from the first fan,
the duct member includes a branch section that branches the cooling air into a first path that guides the cooling air to the first light source and a second path that guides the cooling air to the light modulation section, and
an air-flow amount of the cooling air in the second path is larger than an air-flow amount of the cooling air in the first path.

5. The projector according to claim 4, further comprising:
a circuit substrate that controls at least the light source device and the image forming device, wherein
the duct member guides the cooling air that cooled the first light source via the first path and the cooling air that cooled the light modulation section via the second path to the circuit substrate.

6. The projector according to claim 5, wherein
the cooling device includes a first heat dissipator thermally connected to the first light source and
the first heat dissipator guides the cooling air that passed via the first path to the circuit substrate.

7. The projector according to claim 1, further comprising:
a first detection section that detects a temperature of the first light source and
a second detection section that detects a temperature of the image forming device, wherein
the cooling device controls the first fan based on detection results of the first detection section and the second detection section.

8. A projector comprising:
a light source device;
an image forming device that forms image light from light emitted from the light source device;
a circuit substrate that controls the light source device and the image forming device;
a projection optical device that projects the image light emitted from the image forming device; and
a cooling device that cools the circuit substrate and the image forming device, wherein
the circuit substrate includes a first circuit component, a second circuit component, and a third circuit component,
the image forming device includes a light modulation section that modulates light incident from the light source device based on image information,
the cooling device includes a first fan that supplies cooling air to the first circuit component and the light modulation section,
a heating amount of the first circuit component is less than a heating amount of the second circuit component and a heating amount of the third circuit component,
among the first circuit component, the second circuit component, and the third circuit component, the third circuit component has a highest heating amount and the second circuit component has a lowest management temperature, and
the cooling device adjusts an air-flow amount of the cooling air by the first fan based on temperature information of the image forming device and temperature information of the first circuit component.
